(19) United States
(12) Patent Application Publication
(10) Pub. No.: US 2026/0143831 A1
(43) Pub. Date: May 21, 2026

(54) Two-Color Monolithic Infrared nBn Photodetector Array with High-Density Vertically Integrated Photodiode (HDVIP) Architecture

(71) Applicants: Christoph H. Grein, Wheaton, IL (US); Silviu Velicu, Willowbrook, IL (US)

(72) Inventors: Christoph H. Grein, Wheaton, IL (US); Silviu Velicu, Willowbrook, IL (US)

(21) Appl. No.: 19/366,042

(22) Filed: Oct. 22, 2025

Related U.S. Application Data
(60) Provisional application No. 63/710,109, filed on Oct. 22, 2024.

(51) Int. Cl. H10F 39/10; G01J 1/44

(52) U.S. Cl. CPC H10F 39/103; G01J 1/44; G01J 2001/448

(57) ABSTRACT

A molecular beam epitaxy (MBE)-grown two-color infrared nBn photodetector array integrated within a High-Density Vertically Integrated Photodiode (HDVIP) architecture. The innovative photodetector offers simultaneous detection of two distinct infrared spectral bands with enhanced sensitivity, reduced dark current, and fast response times. This innovative photodetector finds applications in various fields, including thermal imaging, security systems, environmental monitoring, and aerospace technology.

This application claims the benefit of U.S. Provisional Application 63/710,109, filed Oct. 22, 2024.

### BACKGROUND

Semiconductors are either naturally occurring or artificially synthesized materials in which the atomic arrangements give rise to specific atomic potentials that hinder electrical carriers (electrons or positive charges, known as holes) from moving freely and causing electrical currents. The semiconductors act as insulators for as long as there is no additional energy provided to excite these carriers across the band gap that is generated by the atomic potentials. An electrical current can be obtained by the excitation of electrons across the band gap. The necessary energy can be generated in different ways, and of interest for a radiation detector is the energy carried by electromagnetic waves. The incoming radiation must be tuned so that it carries enough energy to be able to excite the electrons across the band gap of the semiconductor. A photodetector senses, either directly or indirectly, the electrons excited by the incoming radiation.

Semiconductors may be intentionally doped with small concentrations of foreign atoms that either add electrons to the number of carriers (n-type doping), or add holes to the number of carriers (p-type doping). In the case of a material that is n-type doped, holes are the minority carriers, whereas for a material that is p-type doped, electrons are the minority carriers. A commonly employed semiconductor for infrared detection and imaging is the alloy Hg₁₋ₓCdₓTe (MCT).

A crystal is defined to be a periodically ordered arrangement of atoms. The atoms hold positions that can be associated with a well-defined grid (or lattice) having small or nonexistent deviations from the grid positions throughout the entire crystal. The periodicity in the atomic arrangements is of utmost importance for the electrical behavior of the crystal.

Molecular Beam Epitaxy (MBE) is a chemical vapor deposition method in which a crystal or layered structure is grown on a substrate within a chamber. The substrate is brought to, and kept at, a predefined growth temperature by a heating element typically placed behind the substrate. This is to ensure that sufficient energy is transferred to the substrate's surface to achieve specific reactions.

The structure is grown by providing atomic and/or molecular fluxes obtained by thermal evaporation of the charge materials. The growth process occurs in an ultra-high vacuum environment to minimize the presence of foreign atoms. Polycrystalline and/or amorphous materials are loaded into crucibles and constitute the charges. The fluxes are adjusted by controlling the temperatures of the charge materials. In this way, the incoming atoms/molecules from the charges must spend a certain residence time on the surface while traveling/diffusing around to find a geometrical position that minimizes the surface energy. Shutters between the charges or charge materials in the effusion cells and substrate are individually controllable. They permit/forbid the flow of molecular beams of the materials that are controlled at a particular time.

Certain materials, material systems, material composites and material structures known collectively as photosensors or photodetectors can produce a detectable change in electrical signal(s), such as a current or changing conductance, when light or waves of electromagnetic radiation are intercepted by the photodetector. A photodetector often comprises a structure consisting of a conductive cathode in contact with a photoconductive material or photovoltaic junction and an anode contact. Electronic detection of photons is accomplished by applying an electrical bias voltage or electric field between the two electrodes (anode and cathode) of a photodetector, measuring the signal apparent in the photodetector and relating that signal to the intensity of the electromagnetic radiation incident on the detector. Further information of such photodetectors may be found in U.S. Pat. Nos. 5,912,464; 6,111,254; 5,300,915; 5,021,663; 5,512,748; and 5,589,688.

Imaging devices are then assembled from a one, two or three-dimensional array of any such photodetectors. These photodetectors may be in electrical contact with a grid of photodetector sites known as pixels with their own electrical contacts which in turn are connected to auxiliary electronics such as amplifiers and then can be individually addressed. The physical pixel electrodes, the addressing scheme, auxiliary electronics, pixel definition, pixel density, pixel size, data read speed, analog-to-digital conversion, electron well capacity, dynamic range and other electronic behaviors are known collectively within the framework of a readout integrated circuit (“ROIC”). Further information of such ROICs may be found in U.S. Pat. Nos. 9,410,850; 5,431,328; 7,462,831; 5,196,703; and 4,659,928.

In a typical imaging array, each photodetector has its own preamplifier, and each preamplifier is connected to address logic and output amplifiers, such that the signal current can be measured at each photodetector and its value communicated to subsequent electronic systems. The array of analog and digital circuitry that measures and communicates the current from each photodetector in the array can be, and is often contained in, an ROIC, which is fabricated on a wafer separately from the photodetector array. There exist many possible embodiments for the electronics and methods present within a ROIC, and geometries for the array of photodetectors. However, many ROICs designed for hybridization possess an anode and a cathode contact for each photodetector in the array. At each photodetector location (pixel), one or more contacts may be present, depending on the number of co-located photodetectors.

These ROICs are subsequently placed in contact with an accompanying grid of photodetectors. This contact can originate in various ways such as: physical contact between the two-pixel grids through an interposing conductive contact soft metal such as indium; through direct deposition of the photodetectors upon the ROIC and possible subsequent pixel definition through chemical, mechanical or optical etching; or other means not listed here. Each technique has limitations and difficulties in use as well as various cost and complexity issues.

High-Density Vertically Integrated Photodiodes (HDVIP) have played a major role in infrared imaging systems by offering high sensitivity and resolution. However, the ability to simultaneously capture multispectral information, particularly in the infrared region, remains a challenge. Conventional crystalline semiconductor photodetectors integrated into HDVIP architectures often lack the required spectral selectivity, limiting their utility in applications requiring multispectral imaging capabilities. Further information may be found in U.S. Pat. Nos. 8,634,005 and 9,293,497.

Innovative infrared focal plane arrays (IRFPAs) capable of detecting across multiple spectral bands hold promise for various scenarios. Traditionally, connecting detector diodes to a silicon ROIC in such devices has relied on indium bumps. However, the HDVIP architecture for single-color IRFPAs, as depicted in FIG. 1, is distinct for two key reasons:
1. It employs reactive ion etching (RIE) and ion implantation to create a flat array of diodes. This eliminates the need for mesa etching to define individual array pixels, which is typical in other architectures, thus avoiding subsequent passivation of trenches.
2. The HDVIP architecture directly bonds detector material to the ROIC and utilizes vertically oriented interconnects via small holes (vias) in the detector material to establish contact with the ROIC.

The monocolor HDVIP foundation can be employed in multispectral IRFPAs.

The monocolor HDVIP architecture can be in the form of extended multispectral IRFPAs within the prior art. In addition to retaining all the advantages of the HDVIP approach, such as mechanical stability across various thermal conditions, including cryogenic temperatures, this extension offers several notable benefits:
1. The structure delivers fully separated color signals to the ROIC, eliminating the need for color subtraction at the ROIC level.
2. It enables the utilization of existing monocolor ROICs to create high-performance demonstration arrays.
3. Arrays can be fabricated using various materials, including HgCdTe, via techniques such as MBE.
4. The processing independence from HgCdTe cutoffs allows for mixed cutoffs within a lot.

A schematic cross-section illustrating a pixel of a prior art two-color multispectral array is depicted in FIG. 2. The fabrication process for this array corresponds similarly to the monocolor array illustrated in FIG. 1.

An additional via is required for each pixel in the bottom MCT layer (as depicted on the right side of FIG. 2) to create this type of two-color array. These vias are insulated with ZnS prior to metal deposition. The metal establishes contact with the underlying ROIC bond pads. The insulation ensures that there is no electrical contact between these metal interconnects, which will later connect to the n-type regions of the top MCT layer, and the n-type regions of the bottom MCT layer.

Subsequently, a second piece of thin p-type, copper-doped MCT, coated with CdTe passivation on both sides, is affixed on top of the structure. This top MCT layer differs from the bottom layer solely in the deposition of an anti-reflection coating before epoxy bonding, apart from the difference in cutoff wavelength. These coatings, situated on either side of the central epoxy strip, are essential for efficiently transmitting infrared radiation from the top MCT layer, through the epoxy, and into the bottom layer.

Vias are then cut through this top MCT layer, aligning with the insulating vias in the bottom layer, to expose the underlying metal. RIE and ion implantation into the via walls, followed by annealing, form the n-type regions of the top diodes. Subsequently, metal is deposited and patterned to create interconnects between the n-type regions of the diodes in the top MCT layer and the underlying metal stubs through the lower insulating vias, which connect to the ROIC. Finally, the top interconnect grid is deposited to ensure contact with the p-type region of the top MCT layer, and a two-color anti-reflection coating is applied. The resultant structure features spatially co-located pixels, facilitating simultaneous detection in both wavelength regions.

Further information of such photodetectors and other two color HDVIP-based architectures distinct from the present invention may be found in U.S. Pat. Nos. 5,912,464; 6,111,254; 5,300,915; 5,021,663; 5,512,748; 5,589,688; 7,759,644; and 8,772,717. An MBE-grown, two-color infrared nBn photodetector integrated within an HDVIP architecture similar to this invention is described in the report “Multispectral HDVIP Focal Plane Arrays” found on the internet at https://apps.dtic.mil/sti/tr/pdf/ADA399260.pdf.

The nBn photodetector is an infrared detector design that significantly reduces dark current and noise compared to other infrared detectors, such as p-n photodiodes. It consists of two n-type semiconductors sandwiching a barrier layer. The barrier layer minimizes dark current and passivates the active layer of the device. It can readily be extended to two-color infrared detection in a non-HDVIP architecture, see U.S. Pat. No. 7,737.411. Its advantages include: (i) The nBn design achieves lower dark current by reducing Shockley-Read-Hall generation currents. This can result in better performance than conventional pn or pin photodiodes. (ii) The nBn design benefits materials lacking good passivation choices.

Other relevant patents and prior art related to nBn infrared detectors include U.S. Pat. Nos. 7,737,411; 8,928,029; and 10,872,987.

### SUMMARY

The present invention introduces a molecular beam epitaxy (MBE)-grown two-color infrared nBn photodetector integrated within an HDVIP architecture, enabling simultaneous detection of two distinct infrared spectral bands. The photodetector is fabricated using MBE techniques to achieve precise control over material properties, resulting in enhanced performance characteristics.

An exemplary embodiment provides a molecular beam epitaxy (MBE)-grown two-color infrared nBn photodetector integrated within a High-Density Vertically Integrated Photodiode (HDVIP) architecture. The photodetector can comprise two distinct photodetectors grown using MBE techniques, each optimized for different infrared spectral bands. The photodetector can exhibit enhanced sensitivity and reduced dark current for each infrared spectral band. The photodetector can feature fast response times suitable for high-speed multispectral infrared imaging applications.

The present invention is distinct in that (i) it has a substantially different contacting scheme, (ii) it does not require the choice of CdTe as the barrier layer material, and (iii) it specifies the non-trivial doping necessary for successful operation.

An exemplary embodiment of the invention provides an infrared nBn photodetector integrated within an HDVIP architecture that can be fabricated from MCT, although other material systems can also be employed. The triple material layer structure of the innovation comprises two copper-doped p-MCT absorber layers with appropriate cutoffs for the two colors of infrared radiation to be detected, such as a lower LWIR-sensing copper-doped p-MCT layer and an upper MWIR-sensing copper-doped p-MCT layer, separated by an arsenic-doped layer of MCT (or “electron barrier”) with an energy gap greater than those of the other two layers. The doping in the central layer, the electron barrier, must permit hole current flow from the p-region of the bottom MCT layer to the p-region of the top layer, and subsequently out through the adjacent contact.

An n-type region is formed in the p-type MWIR region surrounding a first via. A left-side n-type region is formed in the p-type LWIR region surrounding the first via and a right-side n-type region is formed in the p-type region LWIR around a second via.

The large energy gap layer, electron barrier, isolates two n-type regions of the diode to be formed. The material architecture is pBp. After the two n-type regions have been formed, the material architecture becomes nBn in the vicinity of the p-type to n-type converted regions. Two infrared colors “LWIR” and “MWIR” are in the infrared spectrum, with the absorption cutoff or the “LWIR” layer being longer in wavelength than that of the “MWIR” layer.

A triple MCT layer structure is grown by MBE as follows. Upon a CdTe or CdZnTe substrate, a thin absorber layer (5-10 μm) of p-type, copper-doped MCT with the smaller band gap of the two colors is first grown. Then an arsenic-doped layer of MCT with an energy gap greater than those of the two absorber layers is deposited. This is followed by the second color absorber layer, also p-type, copper-doped MCT. An anneal is performed to activate the arsenic atoms in the center layer to act as p-type dopants. The substrate is thinned if needed. The structure is then affixed using epoxy to the array region of a ROIC.

Etching is employed to cut vias through the MCT down to the bond pads of the ROIC. This step, combined with ion implantation into the via walls and subsequent annealing, forms the n-type regions of the diodes. Etching techniques include RIE, ion beam milling, inductively coupled plasma (ICP), electron cyclotron resonance (ECR), and hybrid ICP-RIE.

Another etching technique is employed to remove the “MWIR” layer over every second via.

Metal is deposited into all vias, followed by patterning, establishing connections between the ROIC bond pads and the n-type regions of the MCT diodes.

The entire structure is passivated with a CdTe layer on the top.

A metal interconnect grid is deposited and patterned atop the array, ensuring contact with the p-type portions of the diodes at the pixel corners.

Finally, an antireflection coating 66 is deposited onto the array's top surface to optimize its optical absorption in both infrared spectral bands.

The MBE-grown two-color infrared photodetector finds applications in various fields, including:
Thermal Imaging: Enables the simultaneous detection of different temperature gradients for enhanced thermal mapping and analysis.
Security Systems: Facilitates the identification of concealed objects and intruders through multispectral infrared imaging.
Environmental Monitoring: Allows for the detection and characterization of pollutants, gas leaks, and thermal anomalies in the environment.
Aerospace Technology: Enables multispectral imaging for remote sensing, surveillance, and target detection in aerospace applications.

The integration of an MBE-grown two-color infrared nBn photodetector within the HDVIP architecture represents a significant advancement in multispectral infrared imaging technology. By enabling simultaneous detection of two distinct infrared spectral bands with enhanced sensitivity and reduced dark current, this invention expands the capabilities of HDVIP devices across various applications. The precision and reliability offered by MBE techniques make this innovation highly promising for the future of multispectral infrared imaging.

Numerous other advantages and features of the present invention will be become readily apparent from the following detailed description of the invention and the embodiments thereof, and from the accompanying drawings.

### BRIEF DESCRIPTION OF THE DRAWINGS

FIG. 1A is a schematic sectional view of a prior art single color HDVIP-based detector IRFPA.

FIG. 1B is a schematic plan view of the prior art two color HDVIP-based detector IRFPA of FIG. 1A.

FIG. 2 is a schematic sectional view of a prior art two color HDVIP-based detector IRFPA technology.

FIG. 3 is a schematic sectional view of an exemplary embodiment of a two color HDVIP-based detector array according to the invention.

FIG. 4 is a graph of a P-type dopant concentration of example triple active layers of the embodiment of FIG. 3.

FIG. 5 is a graph of a conduction band (CB) and a valence band (VB) edge energies along the active portions of device length of the embodiment of FIG. 3.

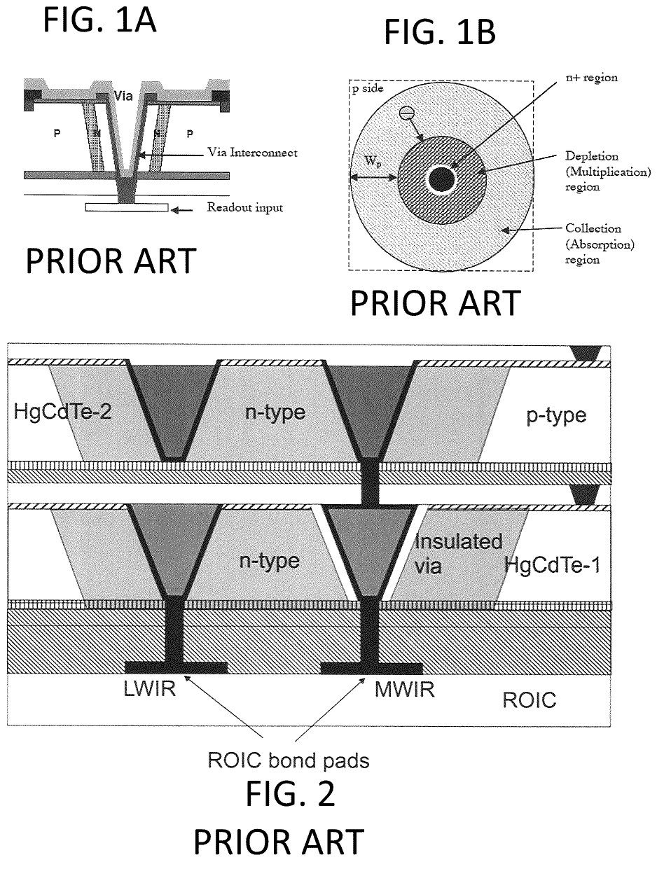

### DETAILED DESCRIPTION

While this invention is susceptible of embodiment in many different forms, there are shown in the drawings, and will be described herein in detail, specific embodiments thereof with the understanding that the present disclosure is to be considered as an exemplification of the principles of the invention and is not intended to limit the invention to the specific embodiments illustrated.

This application incorporates by reference U.S. Provisional Application 63/710,109, filed Oct. 22, 2024 in its entirety.

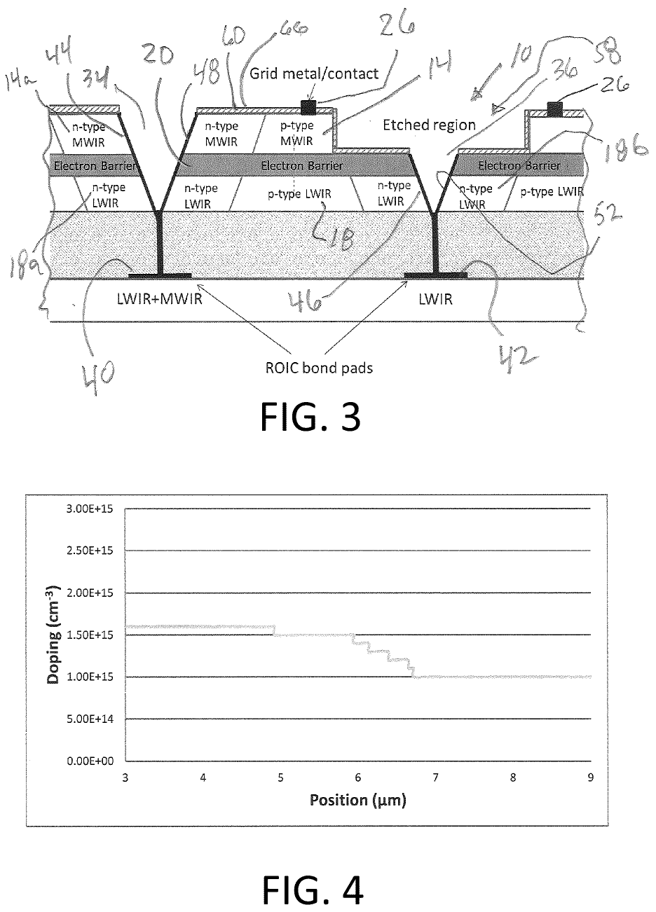

As shown in FIG. 3, an infrared nBn photodetector 10 is integrated within an HDVIP architecture for the special case that it is fabricated from MCT, although other material systems can also be employed. The triple material layer structure of the innovation comprises two copper-doped p-MCT absorber layers 14, 18 with appropriate cutoffs for the two colors of infrared radiation to be detected (such as “MWIR” and “LWIR”), separated by an arsenic-doped layer of MCT (“electron barrier”) 20 with an energy gap greater than those of the other two layers. The doping in the central layer, the electron barrier 20, must permit hole current flow from the p-region of the bottom MCT layer 18 to the p-region of the top layer 14, and subsequently out through the adjacent contact 26.

An n-type region 14a is formed in the p-type MWIR region 14 surrounding a via 34. A left-side n-type region 18a is formed in the p-type LWIR region 18 surrounding the via 34 and a right-side n-type region is formed in the p-type region LWIR 18 around a via 36.

The large energy gap layer, electron barrier 20, isolates two n-type regions 14a, 18a of the detector to be formed. The material architecture is initially pBp. After the two n-type regions have been formed, the material architecture becomes nBn in the vicinity of the p-type to n-type converted regions. The two infrared colors are labeled as “LWIR” and “MWIR” in FIG. 3 and are arbitrary in the infrared spectrum, with the absorption cutoff or the “LWIR” layer being longer in wavelength than that of the “MWIR” layer.

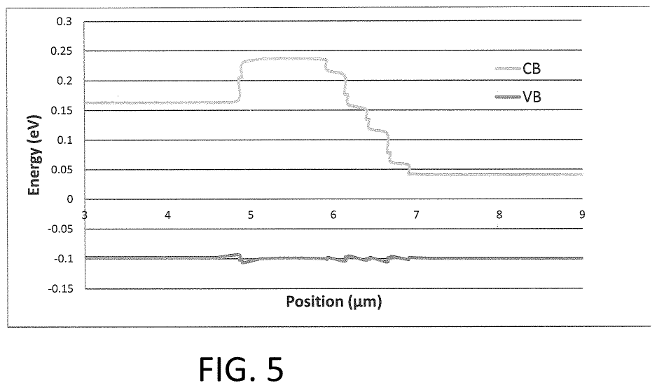

The choice of doping of the three active layers is important. The successful operation of the full device requires that holes in the layer marked “p-type LWIR” 18 in FIG. 3 can transport to the top “grid metal/contact” 26 by passing through the “electron barrier” 20 and “p-type MWIR” layers 14. An appropriate choice of the doping profile is seen in FIG. 4. FIG. 4 shows the p-type doping concentration along the vertical dashed line in FIG. 3. In FIG. 4, the barrier and its adjacent compositional/doping gradients extends approximately 5-7 μm along the position axis. The “p-type LWIR” layer 18 extents to the right of 7 μm, and the “p-type MWIR” layer 14 extends to the left of 5 μm. The choice of 1×10¹⁵ cm⁻³ p-type doping in the “p-type LWIR” layer 18 is arbitrary, but the barrier and “p-type MWIR” layers 14 must have proportionally greater doping levels to facilitate hole transport. The resulting conduction and valence band profiles are depicted in FIG. 5. The success of the chosen doping profile is evidenced in the “p-type MWIR” layer 14 and “electron barrier” 20 valence band edges lying at the same, and not lower, energies than the “p-type LWIR” valence band edge.

The fabrication method for two color HDVIP arrays is outlined as follows, providing a straightforward process:
1. A triple MCT layer structure is grown by MBE as follows. Upon a CdTe or CdZnTe substrate, a thin absorber layer (5-10 μm) of p-type, copper-doped MCT 18 with the smaller band gap of the two colors is first grown (indicated as “LWIR” in FIG. 3). Then an arsenic-doped layer of MCT 20 with an energy gap greater than those of the two absorber layers is deposited. This is followed by the second color absorber layer, also p-type, copper-doped MCT 14 (indicated as “MWIR” in FIG. 3). An anneal is performed to activate the arsenic atoms in the center layer to act as p-type dopants. The substrate is thinned if needed. The structure is then affixed using epoxy to the array region of a ROIC.
2. Etching is employed to cut vias 34, 36 through the MCT down to the bond pads 40, 42 of the ROIC, as shown in FIG. 3. This step, combined with ion implantation 44, 46 into the via walls and subsequent annealing, forms the n-type regions of the diodes. Etching techniques include RIE, ion beam milling, inductively coupled plasma (ICP), electron cyclotron resonance (ECR), and hybrid ICP-RIE.
3. A Step 2 etching technique is employed to remove the “MWIR” layer over every second via, marked “etched region” 58 on the right side in FIG. 3.
5. Metal is deposited into all vias, followed by patterning, establishing connections 48, 52 between the ROIC bond pads 40, 42 and the n-type regions of the MCT diodes.
4. The entire structure is passivated with a CdTe layer 60 on the top.
6. A metal interconnect grid 26 is deposited and patterned atop the array, ensuring contact with the p-type portions of the diodes at the pixel corners.
7. Finally, an antireflection coating 66 is deposited onto the array's top surface to optimize its optical absorption in both infrared spectral bands.

The readout of the detector array is such that the LWIR signal is collected from the right contact 42 of the unit cell depicted in FIG. 3, and the sum of LWIR and MWIR signals are collected from the left contact 40. Subsequent signal processing can be used to isolate the MWIR signal.

The principal advantage of the invention over the conventional two color HDVIP technology depicted in FIG. 2 is that there is no need to epoxy one color array on top of another, which presents alignment and wafer flatness issues, and the epoxy is not completely infrared light transmissive

Some Features of MBE-Grown Two-Color Infrared nBn Photodetector on HDVIP:
1. Simultaneous Multispectral Detection: The integration of two distinct photodetectors grown using MBE techniques allows for simultaneous detection of two different infrared spectral bands, enabling multispectral imaging without the need for additional optical components.
2. Enhanced Sensitivity: The MBE-grown photodetectors offer enhanced sensitivity within their respective infrared bands, facilitating the detection of faint infrared signals with exceptional clarity and precision.
3. Reduced Dark Current: The precise control over material growth in MBE facilitates the fabrication of structures with minimized dark current, resulting in improved signal-to-noise ratio and low-light performance for both spectral bands.
4. Fast Response Times: The optimized carrier transport properties within the MBE-grown structures enable rapid signal detection, ensuring high-speed imaging capabilities crucial for dynamic infrared scenes.

The integration of an MBE-grown two-color infrared nBn photodetector within the HDVIP architecture represents a significant advancement in multispectral infrared imaging technology. By enabling simultaneous detection of two distinct infrared spectral bands with enhanced sensitivity and reduced dark current, this invention expands the capabilities of HDVIP devices across various applications. The precision and reliability offered by MBE techniques make this innovation highly promising for the future of multispectral infrared imaging.

From the foregoing, it will be observed that numerous variations and modifications may be effectuated without departing from the spirit and scope of the invention. It is to be understood that no limitation with respect to the specific apparatus illustrated herein is intended or should be inferred.

1. A molecular beam epitaxy (MBE)-grown two-color infrared nBn photodetector integrated within a High-Density Vertically Integrated Photodiode (HDVIP) architecture.

2. The MBE-grown two-color infrared nBn photodetector on HDVIP of claim 1, comprising two distinct photodetectors grown using MBE techniques, each optimized for different infrared spectral bands.

3. The MBE-grown two-color infrared nBn photodetector on HDVIP of claim 1, exhibiting enhanced sensitivity and reduced dark current for each infrared spectral band.

4. The MBE-grown two-color infrared nBn photodetector on HDVIP of claim 1, featuring fast response times suitable for high-speed multispectral infrared imaging applications.

5. An infrared photodetector, comprising:
a triple material layer structure comprising two copper-doped p-MCT absorber layers with appropriate cutoffs for the two colors of infrared radiation to be detected, such as a lower LWIR-sensing copper-doped p-MCT layer and an upper MWIR-sensing copper-doped p-MCT layer, separated by an electron barrier of an arsenic-doped layer of MCT with an energy gap greater than those of the other two layers, wherein the doping in the electron barrier permit hole current flow from the p-region of the bottom MCT layer to the p-region of the top layer, and subsequently out through the adjacent contact.

6. The photodetector according to claim 5 wherein an n-type region is formed in the p-type MWIR region surrounding a first via and a left-side n-type region is formed in the p-type LWIR region surrounding the first via and a right-side n-type region is formed in the p-type region LWIR around a second via.

7. The photodetector according to claim 6, wherein a large energy gap electron barrier layer, isolates two n-type regions of the diode to be formed, and the material architecture is pBp, and after the two n-type regions have been formed, the material architecture becomes nBn in the vicinity of the p-type to n-type converted regions.
